(19) United States
(12) Patent Application Publication
(10) Pub. No.: US 2026/0279445 A1
(43) Pub. Date: Sep. 17, 2026

(54) CONTROL GATE LINE DRIVING CIRCUIT OF FLASH MEMORY

(71) Applicant: Shanghai Huahong Grace Semiconductor Manufacturing Corporation, Shanghai (CN)

(72) Inventor: Guangjun YANG, Shanghai (CN)

(21) Appl. No.: 19/471,268

(22) PCT Filed: Nov. 1, 2023
(86) PCT No.: PCT/CN2023/129052

§ 371 Date: Sep. 30, 2025

(30) Foreign Application Priority Data
Oct. 27, 2023 (CN) 202311414057.1

(51) Int. Cl. G11C 16/08; G11C 16/14; H03K 19/0185

(52) U.S. Cl. CPC G11C 16/08; G11C 16/14; H03K 19/018521

(57) ABSTRACT

This invention is for a control gate line driving circuit of a flash memory, including an input circuit, a pull-up circuit, an upper switching circuit, a lower switching circuit, and a pull-down circuit. A bias voltage limits the control end voltage of the upper switching circuit and enables the upper switching circuit to be conducted during flash operation, while second bias voltage limits the control end voltage of the lower switching circuit and enables the lower switching circuit to be conducted. If the control gate line input voltage is at a high level, the lower switching circuit limits the maximum value of the first pull-down node through the second bias voltage. If the control gate line input voltage is at a low level, the pull-up switching circuit limits the minimum value of the first pull-up node through the first bias voltage.

### TECHNICAL FIELD

This application relates to a semiconductor integrated circuit, in particular to a control gate line driving circuit of a flash memory.

### BACKGROUND

Referring to FIG. 1, it illustrates a schematic diagram of a circuit structure of a memory cell 101 of an existing flash memory. Referring to FIG. 2, it illustrates a schematic diagram of a cross-sectional structure of a memory cell 101 of an existing flash memory. The existing flash memory includes a plurality of memory cells 101. The plurality of memory cells 101 are arranged to form an array structure of the flash memory.

Each memory cell 101 is a split-gate floating gate device.

Referring to FIG. 2, the split-gate floating gate device includes a source region 205 and a drain region 206, a plurality of split first gate structures with floating gates 104 located between the source region 205 and the drain region 206, and a second gate structure 103 located between the first gate structures. The first gate structure is provided with control gates 105 located at tops of the floating gates 104.

The split-gate floating gate device is a dual-split-gate floating gate device. The number of the first gate structures is two, which are respectively marked as 102a and 102b.

The split-gate floating gate device is an N-type device. Each of the source region 205 and the drain region 206 is composed of an N+ region.

P-type doped channel regions are located between the source region 205 and the drain region 206, and are covered by each of the first gate structures and the second gate structure 103. The source region 205 and the drain region 206 are both formed on a P-type semiconductor substrate 201 and are self-aligned with outer surfaces of the corresponding two first gate structures. Areas between the channel regions are composed of the P-type semiconductor substrate 201 between the source region 205 and the drain region 206 or are formed by further doping on the P-type semiconductor substrate 201.

The drain region 206 of the memory cell 101 is connected to a drain D.

The source region 205 of the memory cell 101 is connected to a source S.

Each first gate structure is formed by stacking a tunneling dielectric layer 202, a floating gate 104, a control gate dielectric layer 203, and a control gate 105.

Each second gate structure 103 is formed by stacking a word line gate dielectric layer 204 and a word line gate 106.

The control gate 105 is connected to a control gate line CG. In FIG. 1, description is made by taking that the control gates 104 of the two first gate structures of the memory cell 101 are both connected to the same control gate line CG as an example. The word line gate 106 is connected to a word line WL.

When an erasing operation is performed on the memory cell 101,
the control gate line CG is connected to negative erasing voltage;
the word line WL is connected to positive erasing voltage;
the drain D and the source S are both connected to 0V;
a voltage difference between the negative erasing voltage and the positive erasing voltage enables the charges stored in each floating gate 104 to be erased.

When a programming operation is performed on the memory cell 101, the control gate line CG is connected to positive programming voltage; the positive programming voltage may be equal to or greater than the positive erasing voltage;
the word line WL is connected to second positive high voltage, and the second positive high voltage is greater than or equal to third threshold voltage of the second gate structure 103;
the source S is connected to third positive high voltage;
the drain D is connected to programming current; the third positive high voltage is greater than the second positive high voltage, and the positive erasing voltage is greater than the third positive high voltage.

When a reading operation is performed on the memory cell 101,
the control gate line CG is connected to 0V;
the word line WL is connected to fourth positive high voltage;
the source S is connected to 0V;
the drain D forms reading current.

Table 1 lists the specific parameters for operating the memory cell 101 in the existing memory:

TABLE 1

| Operation | CG (V) | WL (V) | S (V) | d |
|---|---|---|---|---|
| Programming | 8 | 1.5 | 5 | Idp |
| Erasing | −7 | 8 | 0 | 0 |
| Reading | 0 | 2.5 | 0 | I |

In Table 1, the negative erasing voltage is equal to −7V, and the positive erasing voltage is equal to 8V; the second positive high voltage is equal to 1.5V, the third positive high voltage is equal to 5V, and Idp represents programming current; the fourth positive high voltage is equal to 2.5V, and I represents reading current output by the drain D.

In the flash memory, the memory cells 101 are arranged to form an array structure. In the array structure, the control gates 105 of the first gate structures in the same row of the memory cells 101 in the same row are connected to the control gate lines CG in the same row.

When the flash memory is operated, it is necessary to provide operating voltage for the control gate line CG, such as 8V, −7V and 0V as shown in Table 1, which is achieved through a decoding circuit.

Referring to FIG. 3, it illustrates a diagram of a circuit structure of an existing decoding circuit. Referring to FIG. 4, it illustrates a circuit diagram of a driving circuit in an existing decoding circuit. The existing decoding circuit includes a logic decoding circuit 1, a level shifting circuit 2, and a driving circuit 3.

A power supply end of the logic decoding circuit 1 is connected to power supply voltage VDD.

An input end of the logic decoding circuit 1 decodes an input signal, such as an address signal, to form a first decoding signal. The high level of the first decoding signal is the power supply voltage VDD. The logic decoding circuit 1 mainly obtains the first decoding signal through a logic operation and does not perform level conversion. Therefore, the first decoding signal cannot be directly used as a selection signal for selecting an operation area.

As described earlier, when the flash memory is operated, the operating voltage required by the control gate line CG includes positive high voltage and negative high voltage. Therefore, it is also necessary to use the level shifting circuit 2 to perform level shifting on the first decoding signal.

A power supply end of the level shifting circuit 2 is connected to control gate positive power supply voltage VCGB. A grounding end is connected to control gate the negative power supply voltage Vneg. VCGB is 8V as shown in Table 1, while Vneg may be −7V as shown in Table 1.

The level shifting circuit 2 typically includes two differential input ends, which are respectively connected to the first decoding signal and an inverted signal of the first decoding signal.

The level shifting circuit 2 includes two output ends, which respectively output a first selection inverted signal selbh and a first selection signal selh. The first selection inverted signal selbh and the first selection signal selh are mutually inverted. The high levels are both the control gate positive power supply voltage VCGB. The low levels of the first selection inverted signal selbh and the first selection signal selh are both the control gate negative power supply voltage Vneg.

Typically, the level shifting circuit 2 typically includes two levels of level shifting subunits to achieve the output of the first selection inverted signal selbh and the first selection signal selh, which will not be described in detail in this application.

A power supply end of the driving circuit 3 is connected to control gate line input voltage XPCG<m:0>. Usually, sequential operation will simultaneously apply voltage to the control gate lines CG in a plurality of rows. The control gate line input voltage XPCG<m:0> indicates that voltage can be simultaneously applied to the control gate lines CG in m+1 rows at once, and the voltage applied to each row can be determined according to the actual memory cell 101 and whether the corresponding memory bit is selected. The values of each bit of the control gate line input voltage XPCG<m:0> include a value corresponding to the high level and a value corresponding to the low level. For example, according to data in Table 1, during programming, in a case that the memory bit corresponding to the kth bit in the control gate line input voltage XPCG<m:0> needs to be programmed, since the memory cell 101 in FIG. 1 takes the example of programming two memory bits simultaneously, the value of the kth bit needs to be a high level of 8V and applied to the corresponding control gate line CG during programming, so that the corresponding memory bit will be programmed. In a case that the memory bit corresponding to the (k+1)th bit in the control gate line input voltage XPCG<m:0> does not need to be programmed, the value of the (k+1)th bit needs to be a low level of 0V and applied to the corresponding control gate line CG during programming, so that the corresponding memory bit will not be programmed.

Referring to FIG. 4, the driving circuit 3 includes a first NMOS transistor MN1, a first PMOS transistor MP1, and a second NMOS transistor MN2.

A source of the first NMOS transistor MN1 is connected to the control gate 105, i.e., the corresponding control gate line CG. A drain of the first NMOS transistor MN1 is connected to control gate line input voltage XPCG<m:0>. A gate of the first NMOS transistor MN1 is connected to the first selection signal selh. The high level of the control gate line input voltage XPCG<m:0> is the control gate positive power supply voltage VCGB. In FIG. 4, each bit of data in the control gate line input voltage XPCG<m:0> corresponds to a row of control gate line CG, so the voltage applied to the control gate line CG is also represented by the control gate line output voltage CG<m:0>.

A drain of the first PMOS transistor MP1 is connected to the control gate 105. A source of the first PMOS transistor MP1 is connected to the control gate line input voltage XPCG<m:0>. A gate of the first PMOS transistor MP1 is connected to the first selection inverted signal selbh.

A drain of the second NMOS transistor MN2 is connected to the control gate 105. A source of the second NMOS transistor MN2 is grounded. A gate of the second NMOS transistor MN2 is connected to the first selection inverted signal selbh.

Referring to FIG. 4, the first NMOS transistor MN1, the first PMOS transistor MP1, and the second NMOS transistor MN2 serve as part of the selection circuit of the driving circuit 3 and are configured to connect the control gate line input voltage XPCG<m:0> to the corresponding row line of the control gate 105, thus applying the control gate line output voltage CG<m:0> to the control gate 105. For example, in a case that the first selection inverted signal selbh is 0 and the first selection signal selh is 1, the first NMOS transistor MN1 will be turned on, the first PMOS transistor MP1 will also be turned on, and the control gate line input voltage XPCG<m:0> will be connected to the corresponding row line of the control gate 105 and serve as the control gate line output voltage CG<m:0>. As shown in Table 1, the maximum value of the control gate line input voltage XPCG<m:0> reaches 8V and the minimum value reaches −7V. Similarly, the high level of the first selection signal selh is VCGB, which also reaches 8V, and the low level is Vneg, which also reaches −7V. Finally, the withstand voltage of each transistor of the driving circuit is enabled to be very high. For example, in a case that the first selection signal selh is 1, i.e., 8V, and the control gate line output voltage CG<m:0> is −7V, the gate-source and gate-drain voltage of the first NMOS transistor MN1 will reach 15V. Therefore, in order to satisfy the requirement on the withstand voltage, each transistor of the driving circuit needs to adopt a thick gate oxide structure, and each transistor has a larger size and occupies a larger area. One operation requires m+1 driving circuits as illustrated in FIG. 4, so a larger area is required for the chip.

### BRIEF SUMMARY

According to some embodiments in this application, a control gate line driving circuit of the flash memory disclosed in this application comprising: an input circuit, a pull-up circuit, an upper switching circuit, a lower switching circuit, and a pull-down circuit, wherein
a control end of the input circuit is connected to a first selection signal, the first selection signal is configured to select an operation area of the flash memory, an input end of the input circuit is connected to control gate line input voltage in each row in the operation area, and an output end of the input circuit is connected to a first pull-up node;
the pull-up circuit is connected between control gate positive power supply voltage and the first pull-up node;
the upper switching circuit is connected between the first pull-up node and a first intermediate node, and a control end of the upper switching circuit is connected to first bias voltage; the voltage of the first intermediate node serves as control gate line output voltage in each row;
the lower switching circuit is connected between the first intermediate node and a first pull-down node, and the control end of the upper switching circuit is connected to second bias voltage;
the pull-down circuit is connected between the first pull-down node and control gate negative power supply voltage;
a high level of the control gate line input voltage is a first voltage value, and a low level is a second voltage value; the first voltage value is equal to the control gate positive power supply voltage;
a high level of the first selection signal is a third voltage value, and a low level is a fourth voltage value; the fourth voltage value is taken in a case that the first selection signal is enabled;
when the flash memory is operated, the first selection signal is enabled, and the control gate line driving circuit includes two working states;
a first working state is as follows:
the control gate line input voltage is the first voltage value; the first voltage value is greater than or equal to the fourth voltage value to enable a connection input end of the input circuit to be conducted with a transistor of the first pull-up node;
the pull-up circuit enables the first pull-up node to be connected to the control gate positive power supply voltage, and the voltage of the first pull-up node is equal to the control gate positive power supply voltage;
the upper switching circuit enables the first pull-up node be conducted with the first intermediate node under the control of the first bias voltage, and the voltage of the first intermediate node is equal to the control gate positive power supply voltage;
the lower switching circuit enables the first intermediate node to be conducted with the first pull-down node under the control of the second bias voltage, the voltage of the first pull-down node is equal to the second bias voltage minus second threshold voltage, and the second threshold voltage is the threshold voltage of a transistor of the lower switching circuit;
the pull-down circuit enables the first pull-down node to be disconnected from the control gate negative power supply voltage;
the maximum withstand voltage of a transistor of the pull-down circuit is Vbias2-Vth2-Vneg, where Vias2 is the second bias voltage, Vth2 is the second threshold voltage, and Vneg is the control gate negative power supply voltage;
the maximum withstand voltage of the transistor of the lower switching circuit is VCGB-Vbias2, where VCGB is the control gate positive power supply voltage;
the maximum withstand voltage of a transistor of the upper switching circuit is VCGB-Vbias1, where Vias1 is the first bias voltage;
the maximum withstand voltage of a transistor of the input circuit is VCGB-xdbias, where xdbias represents the fourth voltage value;
a second working state is as follows:
the control gate line input voltage is the second voltage value;
the pull-up circuit enables the first pull-up node to be disconnected from the control gate positive power supply voltage;
the upper switching circuit enables the first pull-up node to be conducted with the first intermediate node under the control of the first bias voltage, the voltage of the first pull-up node is equal to the first bias voltage plus the first threshold voltage, and the first threshold voltage is an absolute value of the threshold voltage of the transistor of the upper switching circuit; the first bias voltage is greater than or equal to the fourth voltage value to enable the connection input end of the input circuit to be conducted with the transistor of the first pull-up node;
the lower switching circuit enables the first intermediate node to be conducted with the first pull-down node under the control of the second bias voltage, and enables the voltage of the first intermediate node to be equal to the voltage of the first pull-down node;
the pull-down circuit enables the first pull-down node to be connected to the control gate negative power supply voltage, and enables the voltage of the first pull-down node to be equal to the control gate negative power supply voltage;
the maximum withstand voltage of a transistor of the pull-up circuit is VCGB-Vbias1-Vth1, where Vth1 is the first threshold voltage;
the maximum withstand voltage of the transistor of the upper switching circuit is Vbias1-Vneg;
the maximum withstand voltage of the transistor of the lower switching circuit is Vbias2-Vneg;
the maximum withstand voltage of the transistor of the input circuit is Vbias1+Vth1-xpcgmin, where xpcgmin represents the second voltage value, the second voltage value is less than or equal to the fourth voltage value, and the second voltage value is greater than or equal to the control gate negative power supply voltage;
the magnitude of the first bias voltage is configured to satisfy the requirement on the maximum withstand voltage of the transistor of the upper switching circuit in the first working state, and satisfy the requirement on the maximum withstand voltage of the transistor of the pull-up circuit, the transistor of the upper switching circuit, the transistor of the lower switching circuit and the transistor of the input circuit in the second working state;
the magnitude of the second bias voltage is configured to satisfy the requirement on the maximum withstand voltage of the transistor of the pull-down circuit and the transistor of the lower switching circuit in the first working state, and satisfy the requirement on the maximum withstand voltage of the transistor of the lower switching circuit in the second working state;
the magnitude of the fourth voltage value is configured to satisfy the requirement on the maximum withstand voltage of the transistor of the input circuit in the second working state.

In some cases, the control gate line driving circuit of the flash memory further includes a second pull-up node, a second intermediate node and a second pull-down node;
the levels of the second pull-up node and the first pull-up node are mutually inverted and interlocked; the second pull-up node is connected to a control end of a connecting transistor between the first pull-up node and the control gate positive power supply voltage; the first pull-up node is connected to a control end of a connecting transistor between the second pull-up node and the control gate positive power supply voltage;
the levels of the second pull-down node and the first pull-down node are mutually inverted and interlocked; the second pull-down node is connected to a control end of a connecting transistor between the first pull-down node and the control gate negative power supply voltage; the first pull-down node is connected to a control end of a connecting transistor between the second pull-down node and the control gate negative power supply voltage;
the levels of the second intermediate node and the first intermediate node are mutually inverted.

In some cases, the input circuit includes a first PMOS transistor and a second PMOS transistor;
a gate of the first PMOS transistor is connected to the first selection signal, a source of the first PMOS transistor is connected to the corresponding control gate line input voltage, and a drain of the first PMOS transistor is connected to the first pull-up node;
a gate of the second PMOS transistor is connected to a second selection signal, the second selection signal is an inverted signal of the first selection signal, and a source of the second PMOS transistor is connected to second positive power supply voltage; the third voltage value is equal to the second positive power supply voltage, and the second PMOS transistor is turned off in a case that the first selection signal is enabled.

In some cases, the second positive power supply voltage is equal to the control gate positive power supply voltage.

In some cases, the first selection signal and the second selection signal are output by a level shifting circuit;
a power supply end of the level shifting circuit is connected to the second positive power supply voltage;
a grounding end of the level shifting circuit is connected to third grounding end power supply voltage, and the magnitude of the third grounding end power supply voltage is the fourth voltage value.

In some cases, a first input end of the level shifting circuit is connected to a first decoding signal output by a logic decoding circuit, a second input end of the level shifting circuit is connected to a second decoding signal, and the second decoding signal is an inverted signal of the first decoding signal;
the first selection signal and the first decoding signal are mutually inverted;
the high levels of the first decoding signal and the second decoding signal are both power supply voltage and the low levels are both 0V.

In some cases, the pull-up circuit includes a third PMOS transistor and a fourth PMOS transistor;
a source of the third PMOS transistor and a source of the fourth PMOS transistor are both connected to the control gate positive power supply voltage;
a drain of the third PMOS transistor and a gate of the fourth PMOS transistor are connected to the first pull-up node;
a drain of the fourth PMOS transistor and a gate of the third PMOS transistor are connected to the second pull-up node.

In some cases, the upper switching circuit includes a fifth PMOS transistor and a sixth PMOS transistor;
a source of the fifth PMOS transistor is connected to the first pull-up node, a drain is connected to the first intermediate node, and a gate is connected to the first bias voltage;
a source of the sixth PMOS transistor is connected to the second pull-up node, a drain is connected to the second intermediate node, and a gate is connected to the first bias voltage.

In some cases, the lower switching circuit includes a first NMOS transistor and a second NMOS transistor;
a source of the first NMOS transistor is connected to the first pull-down node, a drain is connected to the first intermediate node, and a gate is connected to the second bias voltage;
a source of the second NMOS transistor is connected to the second pull-down node, a drain is connected to the second intermediate node, and a gate is connected to the second bias voltage.

In some cases, the pull-down circuit includes a third NMOS transistor and a fourth NMOS transistor;
a source of the third NMOS transistor and a source of the fourth NMOS transistor are both connected to the control gate negative power supply voltage;
a drain of the third NMOS transistor and a gate of the fourth NMOS transistor are connected to the first pull-down node;
a drain of the fourth NMOS transistor and a gate of the third NMOS transistor are connected to the second pull-down node.

In some cases, the maximum value of the first bias voltage is less than or equal to VCGB-2*Vth1;
the minimum value of the second bias voltage is greater than or equal to Vneg+2*Vth2.

In some cases, each memory cell of the flash memory is a split-gate floating gate device;
the split-gate floating gate device includes a first source-drain region and a second source-drain region, a plurality of split first gate structures with floating gates located between the first source-drain region and the second source-drain region, and a second gate structure located between the first gate structures; the first gate structure is provided with the control gate located at the tops of the floating gates; each floating gate is configured to store charges and corresponds to a memory bit;
in a memory array of the flash memory, the control gates of each first gate structure in the same row are all connected to a control gate line in the same row;
when the flash memory is operated, operations in the same operation area include performing voltage driving on the control gate lines in a plurality of rows, and each control gate line is connected to the control gate line output voltage of one in the same row.

In some cases, the split-gate floating gate device is a dual-split-gate floating gate device, and the number of the first gate structures is two.

In some cases, operations on the flash memory include programming, reading, and erasing;
during programming, the control gate line connected to a selected memory bit of a selected memory cell is connected to control gate line programming positive high voltage, and the control gate line connected to a non-selected memory bit is connected to 0V voltage;
during reading, the control gate line connected to the non-selected memory bit of the selected memory cell is connected to control gate line reading positive high voltage, and the control gate line connected to the selected memory bit of the selected memory cell is connected to 0V voltage; the control gate line reading positive high voltage is less than the control gate line programming positive high voltage;
during erasing, the control gate line connected to the selected memory bit of the selected memory cell is connected to control gate line erasing negative high voltage, and the control gate line connected to the non-selected memory bit is connected to 0V voltage.

In some cases, during programming, VCGB is the control gate line programming positive high voltage, Vneg is 0V, and the first bias voltage and the second bias voltage are both configured to half of the control gate line programming positive high voltage or half of the control gate line programming positive high voltage plus or minus a first offset value, the first offset value is less than or equal to half of the control gate line programming positive high voltage minus (Vneg+2*Vth2), and the first offset value is less than or equal to (VCGB-2*Vth1) minus half of the control gate line programming positive high voltage; the fourth voltage value is configured to be equal to the first bias voltage;
during reading, VCGB is the control gate line reading positive high voltage, Vneg is 0V, the power supply voltage is less than (VCGB-2*Vth1), and the first bias voltage is the power supply voltage; the power supply voltage is less than (Vneg+2*Vth2), and the second bias voltage is a value between (Vneg+2*Vth2) and VCGB;
during erasing, VCGB is 0V, Vneg is the control gate line erasing negative high voltage, and the first bias voltage and the second bias voltage are both configured to half of the control gate line erasing negative high voltage or half of the control gate line erasing negative high voltage plus or minus a second offset value, the second offset value is less than or equal to half of the control gate line erasing negative high voltage minus (Vneg+2*Vth2), and the second offset value is less than or equal to (VCGB-2*Vth1) minus half of the control gate line erasing negative high voltage; the fourth voltage value is configured to be equal to the first bias voltage.

In some cases, during programming, the control gate line programming positive high voltage is 8V, and the first bias voltage and the second bias voltage are both 4V; the first voltage value of the control gate line input voltage is equal to 8V, and the second voltage value is less than or equal to 4V;
during reading, the control gate line reading positive high voltage is 4V, and the second bias voltage is 3V; the first voltage value of the control gate line input voltage is equal to 4V, and the second voltage value is less than or equal to 0V;
during erasing, the control gate line erasing negative high voltage is −7V, and the first bias voltage and the second bias voltage are both −4V; the first voltage value of the control gate line input voltage is equal to 0V, and the second voltage value is less than or equal to −7V.

In this application, a pull-up circuit and a pull-down circuit in the driving circuit, as well as an upper switching circuit and a lower switching circuit located between the two are provided. Control ends of the upper switching circuit and the lower switching circuit can be respectively configured with first bias voltage and second bias voltage. The first bias voltage limits the control end voltage of the upper switching circuit and can limit the minimum voltage that can be reached by the first pull-up node at the connection between the pull-up circuit and the upper switching circuit on the premise of ensuring that the upper switching circuit is conducted. Similarly, the second bias voltage limits the control end voltage of the lower switching circuit and can limit the maximum voltage that can be reached by the first pull-down node at the connection between the pull-down circuit and the lower switching circuit on the premise of ensuring that the lower switching circuit is conducted. Therefore, this application can adjust the actual withstand voltage of each transistor in the driving circuit by adjusting the first bias voltage and the second bias voltage. This application can adjust the withstand voltage of each transistor in the driving circuit, so that the high voltage of the driving circuit will not be fully borne by each transistor, and the voltage withstanding capacity actually required for the transistor is reduced. Therefore, transistors with a thinner gate oxide structure can be adopted, thus effectively reducing the area of the driving circuit and reducing the area of the entire flash memory.

In this application, the pull-up circuit and the pull-down circuit can also be configured as an interlocked structure and form two mutually opposite paths, which can further optimize the performance of the circuit.

### BRIEF DESCRIPTION OF THE DRAWINGS

This application will be further described below in detail in combination with the specific embodiments with reference to the drawings.

FIG. 1 illustrates a schematic diagram of a structure of a memory cell of an existing flash memory.

FIG. 2 illustrates a schematic diagram of a cross-sectional structure of a memory cell of an existing flash memory.

FIG. 3 illustrates a diagram of a circuit structure of an existing decoding circuit.

FIG. 4 illustrates a circuit diagram of a driving circuit in an existing decoding circuit.

FIG. 5 illustrates a diagram of a circuit structure of a control gate line driving circuit of a flash memory according to an embodiment of this application.

FIG. 6 illustrates a circuit diagram of a control gate line driving circuit of a flash memory according to an exemplary embodiment of this application.

FIG. 7 illustrates a circuit diagram of a level shifting circuit corresponding to a control gate line driving circuit of a flash memory according to an embodiment of this application.

### DETAILED DESCRIPTION OF THE EMBODIMENTS

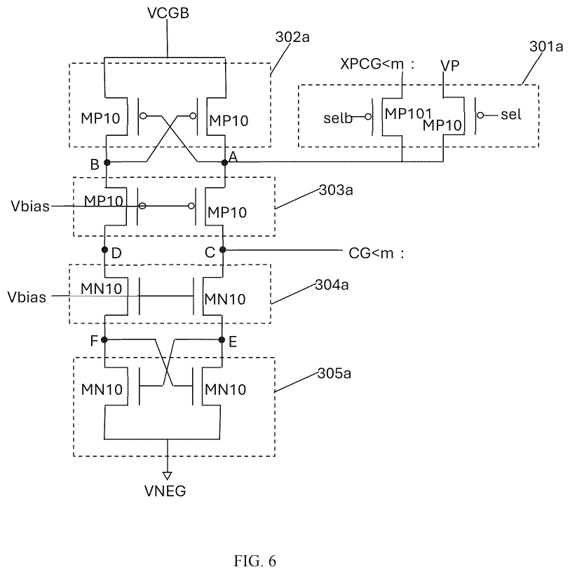

Referring to FIG. 5, it illustrates a diagram of a circuit structure of a control gate line driving circuit of a flash memory according to an embodiment of this application. The control gate line driving circuit of the flash memory according to this embodiment of this application includes an input circuit 301, a pull-up circuit 302, an upper switching circuit 303, a lower switching circuit 304, and a pull-down circuit 305.

A control end of the input circuit 301 is connected to a first selection signal selb. The first selection signal selb is configured to select an operation area of the flash memory. An input end of the input circuit 301 is connected to control gate line input voltage XPCG<m:0> in each row in the operation area. An output end of the input circuit 301 is connected to a first pull-up node A.

the pull-up circuit 302 is connected between control gate positive power supply voltage VCGB and the first pull-up node A.

The upper switching circuit 303 is connected between the first pull-up node A and a first intermediate node C. A control end of the upper switching circuit 303 is connected to first bias voltage Vbias1. The voltage of the first intermediate node C serves as control gate line output voltage CG<m:0> in each row.

The lower switching circuit 304 is connected between the first intermediate node C and a first pull-down node E. The control end of the upper switching circuit 303 is connected to second bias voltage Vbias2.

The pull-down circuit 305 is connected between the first pull-down node E and control gate negative power supply voltage Vneg.

A high level of the control gate line input voltage XPCG<m:0> is a first voltage value, and a low level is a second voltage value. The first voltage value is equal to the control gate positive power supply voltage VCGB.

A high level of the first selection signal selb is a third voltage value, and a low level is a fourth voltage value xdbias. The fourth voltage value xdbias is taken in a case that the first selection signal selb is enabled.

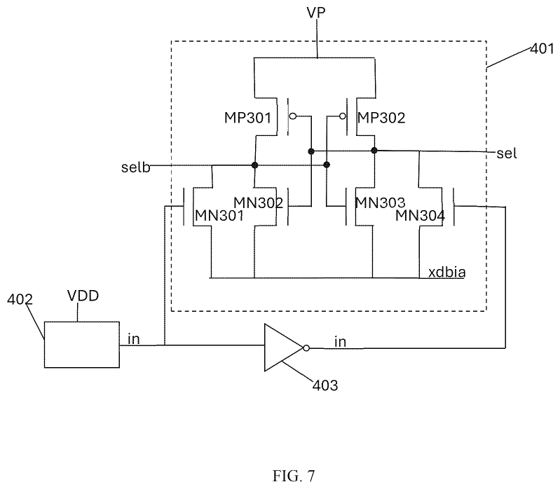

When the flash memory is operated, the first selection signal selb is enabled, that is, the fourth voltage value xdbias is taken, where xdbias is as illustrated in FIG. 7, and the control gate line driving circuit includes two working states.

A first working state is as follows:

The control gate line input voltage XPCG<m:0> is the first voltage value, i.e., high level value VCGB. The first voltage value is greater than or equal to the fourth voltage value xdbias to enable a connection input end of the input circuit 301 to be conducted with a transistor of the first pull-up node A.

The pull-up circuit 302 enables the first pull-up node A to be connected to the control gate positive power supply voltage VCGB. The voltage of the first pull-up node A is equal to the control gate positive power supply voltage VCGB.

The upper switching circuit 303 enables the first pull-up node A be conducted with the first intermediate node C under the control of the first bias voltage Vbias1, and the voltage of the first intermediate node C is equal to the control gate positive power supply voltage VCGB, that is, the control gate line output voltage CG<m:0> is VCGB.

The lower switching circuit 304 enables the first intermediate node C to be conducted with the first pull-down node E under the control of the second bias voltage Vbias2. The voltage of the first pull-down node E is equal to the second bias voltage Vbias2 minus second threshold voltage, i.e., Vbias2-Vth2, where Vth2 represents the second threshold voltage. The second threshold voltage is the threshold voltage of a transistor of the lower switching circuit 304.

From the above, it can be seen that in the first working state, the voltage of both the nodes A and Cis VCGB, and the voltage of the node E is Vbias2-Vth2.

The pull-down circuit 305 enables the first pull-down node E to be disconnected from the control gate negative power supply voltage Vneg.

The maximum withstand voltage of a transistor of the pull-down circuit 305 is Vbias2-Vth2-Vneg, where Vias2 is the second bias voltage Vbias2, Vth2 is the second threshold voltage, and Vneg is the control gate negative power supply voltage.

The maximum withstand voltage of the transistor of the lower switching circuit 304 is VCGB-Vbias2, where VCGB is the control gate positive power supply voltage VCGB.

The maximum withstand voltage of a transistor of the upper switching circuit 303 is VCGB-Vbias1, where Vias1 is the first bias voltage Vbias1.

The maximum withstand voltage of a transistor of the input circuit 301 is VCGB-xdbias, where xdbias represents the fourth voltage value xdbias.

A second working state is as follows:

The control gate line input voltage XPCG<m:0> is the second voltage value, i.e., low level value.

The pull-up circuit 302 enables the first pull-up node A to be disconnected from the control gate positive power supply voltage VCGB.

The upper switching circuit 303 enables the first pull-up node A to be conducted with the first intermediate node C under the control of the first bias voltage Vbias1. The voltage of the first pull-up node A is equal to the first bias voltage Vbias1 plus the first threshold voltage, i.e., Vbias1+Vth1, where Vth1 represents the first threshold voltage. The first threshold voltage is an absolute value of the threshold voltage of the transistor of the upper switching circuit 303. The first bias voltage Vbias1 is greater than or equal to the fourth voltage value xdbias to enable the connection input end of the input circuit 301 to be conducted with the transistor of the first pull-up node A.

The lower switching circuit 304 enables the first intermediate node C to be conducted with the first pull-down node E under the control of the second bias voltage Vbias2, and enables the voltage of the first intermediate node C to be equal to the voltage of the first pull-down node E.

The pull-down circuit 305 enables the first pull-down node E to be connected to the control gate negative power supply voltage, and enables the voltage of the first pull-down node E to be equal to the control gate negative power supply voltage Vneg.

From the above, it can be seen that in the second working state, the voltage of both the nodes E and Cis Vneg, and the voltage of the node A is Vbias1+Vth1.

The maximum withstand voltage of a transistor of the pull-up circuit 302 is VCGB-Vbias1-Vth1, where Vth1 is the first threshold voltage.

The maximum withstand voltage of the transistor of the upper switching circuit 303 is Vbias1-Vneg.

The maximum withstand voltage of the transistor of the lower switching circuit 304 is Vbias2-Vneg.

The maximum withstand voltage of the transistor of the input circuit 301 is Vbias1+Vth1-xpcgmin, where xpcgmin represents the second voltage value, the second voltage value is less than or equal to the fourth voltage value xdbias, and the second voltage value is greater than or equal to the control gate negative power supply voltage Vneg.

The magnitude of the first bias voltage Vbias1 is configured to satisfy the requirement on the maximum withstand voltage of the transistor of the upper switching circuit 303 in the first working state, and satisfy the requirement on the maximum withstand voltage of the transistor of the pull-up circuit 302, the transistor of the upper switching circuit 303, the transistor of the lower switching circuit 304 and the transistor of the input circuit 301 in the second working state.

The magnitude of the second bias voltage Vbias2 is configured to satisfy the requirement on the maximum withstand voltage of the transistor of the pull-down circuit 305 and the transistor of the lower switching circuit 304 in the first working state, and satisfy the requirement on the maximum withstand voltage of the transistor of the lower switching circuit 304 in the second working state.

The magnitude of the fourth voltage value xdbias is configured to satisfy the requirement on the maximum withstand voltage of the transistor of the input circuit 301 in the second working state.

In this embodiment of this application, the control gate line driving circuit of the flash memory further includes a second pull-up node B, a second intermediate node D and a second pull-down node F.

The levels of the second pull-up node B and the first pull-up node A are mutually inverted and interlocked. The second pull-up node B is connected to a control end of a connecting transistor between the first pull-up node A and the control gate positive power supply voltage VCGB. The first pull-up node A is connected to a control end of a connecting transistor between the second pull-up node B and the control gate positive power supply voltage VCGB.

The levels of the second pull-down node F and the first pull-down node E are mutually inverted and interlocked. The second pull-down node F is connected to a control end of a connecting transistor between the first pull-down node E and the control gate negative power supply voltage Vneg. The first pull-down node E is connected to a control end of a connecting transistor between the second pull-down node F and the control gate negative power supply voltage Vneg.

The levels of the second intermediate node D and the first intermediate node D are mutually inverted.

Referring to FIG. 6, it illustrates a circuit diagram of a control gate line driving circuit of a flash memory according to an exemplary embodiment of this application. In this exemplary embodiment of this application, in FIG. 6, an input circuit is individually represented by reference sign 301a, which is configured to implement the input circuit 301 in FIG. 5; a pull-up circuit is individually represented by reference sign 302a, which is configured to implement the pull-up circuit 302 in FIG. 5; an upper switch circuit is individually represented by reference sign 303a, which is configured to implement the upper switch circuit 303 in FIG. 5; a lower switch circuit is individually represented by reference sign 304a, which is configured to implement the lower switch circuit 304 in FIG. 5; a pull-down circuit is individually represented by reference sign 305a, which is configured to implement the pull-down circuit 305 in FIG. 5.

The input circuit 301a includes a first PMOS transistor MP101 and a second PMOS transistor MP102.

A gate of the first PMOS transistor MP101 is connected to the first selection signal selb. A source of the first PMOS transistor MP101 is connected to the corresponding control gate line input voltage XPCG<m:0>. A drain of the first PMOS transistor MP101 is connected to the first pull-up node A.

A gate of the second PMOS transistor MP102 is connected to a second selection signal sel. The second selection signal sel is an inverted signal of the first selection signal selb. A source of the second PMOS transistor MP102 is connected to second positive power supply voltage VP. The third voltage value is equal to the second positive power supply voltage VP. The second PMOS transistor MP102 is turned off in a case that the first selection signal selb is enabled.

In some specific embodiments, the second positive power supply voltage VP is equal to the control gate positive power supply voltage VCGB.

The first selection signal selb and the second selection signal sel are output by a level shifting circuit 401.

The pull-up circuit 302a includes a third PMOS transistor MP103 and a fourth PMOS transistor MP104.

A source of the third PMOS transistor MP103 and a source of the fourth PMOS transistor MP104 are both connected to the control gate positive power supply voltage VCGB.

A drain of the third PMOS transistor MP103 and a gate of the fourth PMOS transistor MP104 are connected to the first pull-up node A.

A drain of the fourth PMOS transistor MP104 and a gate of the third PMOS transistor MP103 are connected to the second pull-up node B. As illustrated in FIG. 6, it can be seen that the third PMOS transistor MP103 and the fourth PMOS transistor MP104 form an interlocked structure.

The upper switching circuit 303a includes a fifth PMOS transistor MP105 and a sixth PMOS transistor MP106.

A source of the fifth PMOS transistor MP105 is connected to the first pull-up node A, a drain is connected to the first intermediate node C, and a gate is connected to the first bias voltage Vbias1.

A source of the sixth PMOS transistor MP106 is connected to the second pull-up node B, a drain is connected to the second intermediate node D, and a gate is connected to the first bias voltage Vbias1.

The lower switching circuit 304a includes a first NMOS transistor MN101 and a second NMOS transistor MN102.

A source of the first NMOS transistor MN101 is connected to the first pull-down node E, a drain is connected to the first intermediate node C, and a gate is connected to the second bias voltage Vbias2.

A source of the second NMOS transistor MN102 is connected to the second pull-down node F, a drain is connected to the second intermediate node D, and a gate is connected to the second bias voltage Vbias2.

The pull-down circuit 305a includes a third NMOS transistor MN103 and a fourth NMOS transistor MN104.

A source of the third NMOS transistor MN103 and a source of the fourth NMOS transistor MN104 are both connected to the control gate negative power supply voltage Vneg.

A drain of the third NMOS transistor MN103 and a gate of the fourth NMOS transistor MN104 are connected to the first pull-down node E.

A drain of the fourth NMOS transistor MN104 and a gate of the third NMOS transistor MN103 are connected to the second pull-down node F. As illustrated in FIG. 6, it can be seen that the third NMOS transistor MN103 and the fourth NMOS transistor MN104 also form an interlocked structure.

In some exemplary embodiments, the maximum value of the first bias voltage Vbias1 is less than or equal to VCGB-2*Vth1. In this way, when the PMOS transistor MP103 is turned off and the node A is Vbias1+Vth1, it can ensure that the source voltage VCGB of the PMOS transistor MP104 minus Vth1 is greater than or equal to Vbias1+Vth1, so the PMOS transistor MP104 can maintain to be turned on.

The minimum value of the second bias voltage Vbias2 is greater than or equal to Vneg+2*Vth2. Similarly, when the NMOS transistor MN103 is turned off and the node E is Vbias2-Vth2, it can ensure that the source voltage Vneg of the NMOS transistor MN104 plus Vth2 is less than or equal to Vbias2-Vth2, so the NMOS transistor MN104 can maintain to be turned on.

Referring to FIG. 7, it illustrates a circuit diagram of a level shifting circuit 401 corresponding to a control gate line driving circuit of a flash memory according to an embodiment of this application. A power supply end of the level shifting circuit 401 is connected to the second positive power supply voltage VP.

A grounding end of the level shifting circuit 401 is connected to third grounding end power supply voltage xdbias. The magnitude of the third grounding end power supply voltage xdbias is the fourth voltage value xdbias, which are both represented by xdbias.

A first input end of the level shifting circuit 401 is connected to a first decoding signal in output by a logic decoding circuit 402. A second input end of the level shifting circuit 401 is connected to a second decoding signal inb. The second decoding signal inb is an inverted signal of the first decoding signal in obtained by inverting the first decoding signal in through an inverter 403.

The first selection signal selb and the first decoding signal in are mutually inverted.

The high levels of the first decoding signal in and the second decoding signal inb are both power supply voltage Vdd and the low levels are both 0V.

Referring to FIG. 7, the main structure of the level shifting circuit 401 includes PMOS transistors MP301 and MP302, and NMOS transistors MN301, MN302, MN303, and MN304. The PMOS transistors MP301 and MP302, and the NMOS transistors MN303 and MN302, form an interlocked circuit structure. Source ends of the PMOS transistors MP301 and MP302 are both connected to the second positive power supply voltage VP. Source ends of the NMOS transistors MN301, MN302, MN303, and MN304 are all connected to the third grounding power supply voltage xdbias. A gate of the NMOS transistor MN301 is connected to the first decoding signal in. A gate of the NMOS transistor MN302 is connected to the second decoding signal inb.

Drains of the NMOS transistors MN301 and MN302 and the PMOS transistor MP301, and gates of the NMOS transistor MN303 and the PMOS transistor MP303, are connected together and output the first selection signal selb.

Drains of the NMOS transistors MN303 and MN304 and the PMOS transistor MP302, and gates of the NMOS transistor MN302 and the PMOS transistor MP301, are connected together and output the second selection signal sel.

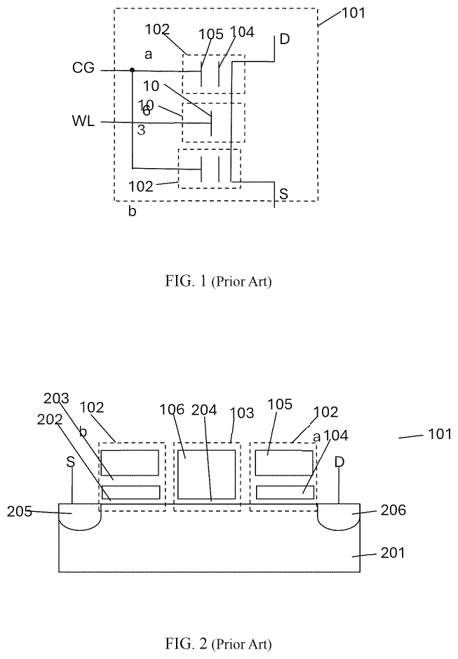

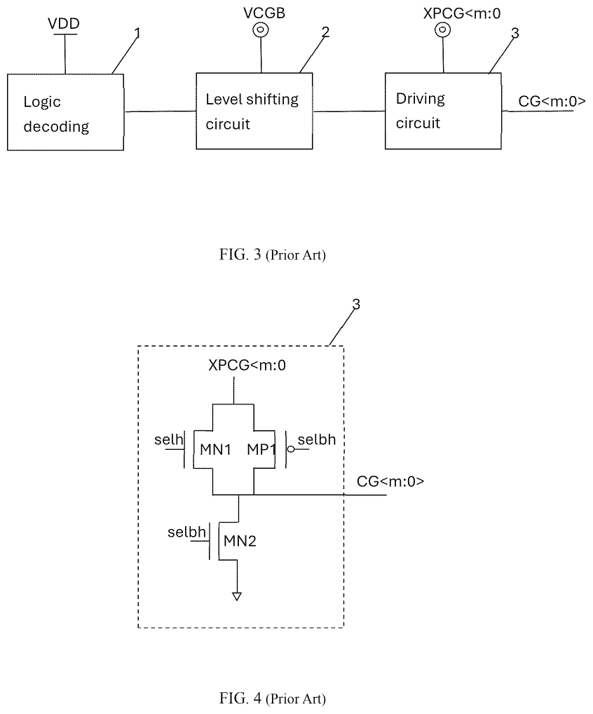

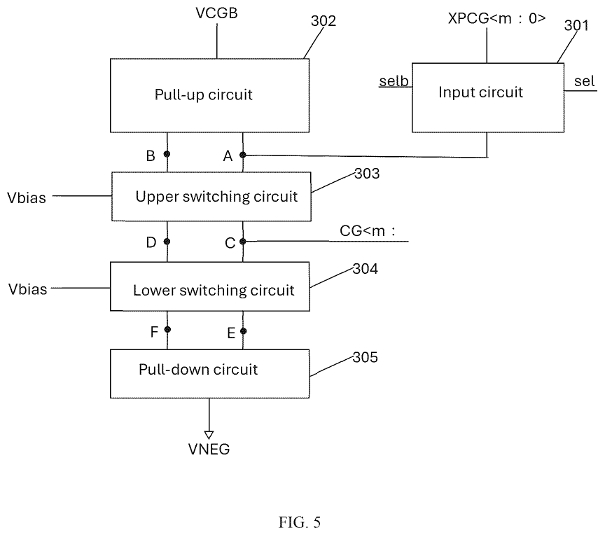

In this embodiment of this application, for the structure of the flash memory, please also refer to FIG. 1 and FIG. 2. The flash memory includes a plurality of memory cells 101. The plurality of memory cells 101 are arranged to form an array structure of the flash memory. Each memory cell 101 is a split-gate floating gate device.

Referring to FIG. 2, the split-gate floating gate device includes a source region 205 and a drain region 206, a plurality of split first gate structures with floating gates 104 located between the source region 205 and the drain region 206, and a second gate structure 103 located between the first gate structures. The first gate structure is provided with control gates 105 located at tops of the floating gates 104.

The split-gate floating gate device is a dual-split-gate floating gate device. The number of the first gate structures is two, which are respectively marked as 102a and 102b.

The split-gate floating gate device is an N-type device. Each of the source region 205 and the drain region 206 is composed of an N+ region.

P-type doped channel regions are located between the source region 205 and the drain region 206, and are covered by each of the first gate structures and the second gate structure 103. The source region 205 and the drain region 206 are both formed on a P-type semiconductor substrate 201 and are self-aligned with outer surfaces of the corresponding two first gate structures. Areas between the channel regions are composed of the P-type semiconductor substrate 201 between the source region 205 and the drain region 206 or are formed by further doping on the P-type semiconductor substrate 201.

The drain region 206 of the memory cell 101 is connected to a drain D.

The source region 205 of the memory cell 101 is connected to a source S.

Each first gate structure is formed by stacking a tunneling dielectric layer 202, a floating gate 104, a control gate dielectric layer 203, and a control gate 105.

Each second gate structure 103 is formed by stacking a word line gate dielectric layer 204 and a word line gate 106.

The control gate 105 is connected to a control gate line CG. In FIG. 1, description is made by taking that the control gates 104 of the two first gate structures of the memory cell 101 are both connected to the same control gate line CG as an example. In other embodiments, the control gates 104 of the two first gate structures in the memory cell 101 may also be independently connected to a row of the control gate lines CG, so that two memory bits formed by the floating gates 104 can be operated independently.

The word line gate 106 is connected to a word line WL.

When the flash memory is operated, operations in the same operation area include performing voltage driving on the control gate lines in a plurality of rows. Each control gate line is connected to the control gate line output voltage CG<m:0> of one in the same row.

Operations on the flash memory include programming, reading, and erasing.

During programming, the control gate line connected to a selected memory bit of a selected memory cell is connected to control gate line programming positive high voltage, and the control gate line connected to a non-selected memory bit is connected to 0V voltage. In Table 1, the control gate line programming positive high voltage corresponds to 8V voltage.

During reading, the control gate line connected to the non-selected memory bit of the selected memory cell is connected to control gate line reading positive high voltage, and the control gate line connected to the selected memory bit of the selected memory cell is connected to 0V voltage. In Table 1, it shows that the control gate line connected to the selected memory bit of the selected memory cell is connected to 0V voltage. Table 1 does not show the control gate line reading positive high voltage. The control gate line reading positive high voltage is less than the control gate line programming positive high voltage. For example, the control gate line reading positive high voltage is 4V.

During erasing, the control gate line connected to the selected memory bit of the selected memory cell is connected to control gate line erasing negative high voltage, and the control gate line connected to the non-selected memory bit is connected to 0V voltage. In Table 1, the control gate line erasing negative high voltage is −7V.

In this embodiment of this application, during programming, VCGB is the control gate line programming positive high voltage, Vneg is 0V, and the first bias voltage Vbias1 and the second bias voltage Vbias2 are both configured to half of the control gate line programming positive high voltage or half of the control gate line programming positive high voltage plus or minus a first offset value, the first offset value is less than or equal to half of the control gate line programming positive high voltage minus (Vneg+2*Vth2), and the first offset value is less than or equal to (VCGB-2*Vth1) minus half of the control gate line programming positive high voltage; the fourth voltage value xdbias is configured to be equal to the first bias voltage Vbias1.

During reading, VCGB is the control gate line reading positive high voltage, Vneg is 0V, the power supply voltage Vdd is less than (VCGB-2*Vth1), and the first bias voltage Vbias1 is the power supply voltage Vdd; the power supply voltage Vdd is less than (Vneg+2*Vth2), and the second bias voltage Vbias2 is a value between (Vneg+2*Vth2) and VCGB.

During erasing, VCGB is 0V, Vneg is the control gate line erasing negative high voltage, and the first bias voltage Vbias1 and the second bias voltage Vbias2 are both configured to half of the control gate line erasing negative high voltage or half of the control gate line erasing negative high voltage plus or minus a second offset value, the second offset value is less than or equal to half of the control gate line erasing negative high voltage minus (Vneg+2*Vth2), and the second offset value is less than or equal to (VCGB-2*Vth1) minus half of the control gate line erasing negative high voltage; the fourth voltage value xdbias is configured to be equal to the first bias voltage Vbias1.

In some embodiments, the following parameters are taken according to Table 2:

TABLE 2

| | Programming | Reading | Erasing |
|---|---|---|---|
| VCGB | 8 | Vdd→4 | 1.5→0 |
| VP | 8 | Vdd→4 | 1.5→0 |
| Vbias1 | 4 | 0→Vdd | 0→−4 |
| Vbias2 | 4 | 3 | 1.5→−4 |
| xdbias | 0→4 | 0→1.5 | 0 (or −4) |
| XPCG | 8/4 (or 8/0) | 1.5→4/0 | 0→−7/0 |
| CG | 8/0 | 1.5→4/0 | 0→−7/0 |
| Vneg | 0 | 0 | 0→−7/0 |

As shown in Table 2, during programming, the corresponding data are in column 1.

The control gate line programming positive high voltage is 8V, that is, the CG corresponding to the selected bit, i.e., the memory bit that needs to be programmed, needs to be applied with 8V, while the CG corresponding to the non-selected bit, i.e., the memory bit that does not need to be programmed, needs to be applied with 0V. The first bias voltage Vbias1 and the second bias voltage Vbias2 are both 4V. The first voltage value of the control gate line input voltage XPCG<m:0> is equal to 8V. The second voltage value is less than or equal to 4V. In Table 2, XPCG represents one bit of data in XPCG<m:0>, 8/4 represents that the XPCG of the row corresponding to the memory bit that needs to be programmed is 8V, and 4 under the forward slash represents that the XPCG of the row corresponding to the memory bit that needs to be programmed is 4V. Since in this embodiment of this application, the second voltage value is less than or equal to 4V, it may also be 0V, such as 8/0 described in Table 2.

In Table 2, VP is equal to VCGB; 0→4 corresponding to xdbias represents that the voltage will change from 0V to 4V; 8/0 of CG represents that the CG corresponding to the bit that to be programmed needs to be applied with 8V, while the CG corresponding to the bit not to be programmed needs to be applied with 0V; Vneg is 0V.

Since VCGB is 8V and Vneg is 0V, taking Vth1 and Vth2 both being 0.7V as an example, where Vth1 represents the absolute value of the threshold voltage of the PMOS transistor, then Vneg+2*Vth2 is equal to 1.4V, VCGB-2*Vth1 is 6.6V, and Vbias1 and Vbias2 may be a value between 1.4V and 6.6V. The effect when 4V is taken is better. At this time, the first offset value is 0V. Since differences between 1.4V and 4V and between 6.6V and 4V are both 2.6V, the maximum value of the first offset value is 2.6V.

Xdbias will change from 0V to 4V.

XPCG includes 8V corresponding to the memory bit to be programmed and 4V or 0V corresponding to the memory bit not to be programmed.

XPCG includes 8V corresponding to the memory bit to be programmed and 0V corresponding to the memory bit not to be programmed.

Vneg is 0V.

During reading, the corresponding data are in column 2 in Table 2.

The control gate line reading positive high voltage is 4V, that is, during reading, the CG corresponding to the non-selected bit, i.t., the memory bit that does not need to be read, needs to be applied with 4V. However, the CG corresponding to the selected bit, i.e., the memory bit that needs to be read, needs to be applied with 0V. The second bias voltage Vbias2 is 3V. The first voltage value of the control gate line input voltage XPCG<m:0> is equal to 4V, and the second voltage value is less than or equal to 0V.

VCGB will change from Vdd to 4V, and VP is equal to VCGB.

Vbias1 changes from 0V to the power supply voltage Vdd, where Vdd is less than VCGB-2*Vth1. Taking Vth1 being 0.7V as an example, VCGB-2*Vth1 is equal to 2.6V.

Vbias2 is equal to 3V. Since Vneg is equal to 0V, taking Vth2 being 0.7V as an example, Vneg+2*Vth2 is equal to 1.6V, so 3V is greater than 1.6V but less than 4V, which satisfies that the second bias voltage Vbias2 is a value between (Vneg+2*Vth2) and VCGB.

Xdbias will change from 0V to 1.5V.

XPCG will change from 1.5V to 4V, or from 1.5V to 0V.

CG will change from 1.5V to 4V, or from 1.5V to 0V.

Vneg is 0V.

During erasing, the corresponding data are in column 3 in Table 2.

The control gate line erasing negative high voltage is −7V, which represents that the CG corresponding to the selected bit, i.e., the memory bit that needs to be erased, is applied with −7V, while the CG corresponding to the non-selected bit, i.e., the memory bit that does not need to be erased, is applied with 0V. The first bias voltage Vbias1 and the second bias voltage Vbias2 are both −4V. The first voltage value of the control gate line input voltage XPCG<m:0> is equal to 0V, and the second voltage value is less than or equal to −7V.

VCGB will change from 1.5V to 0V, and VP is equal to VCGB.

Vbias1 will change from 0V to −4V. Vbias2 will change from 1.5V to −4V. At this time, both Vbias1 and Vbias2 are about half of the control gate line erasing negative high voltage, i.e., −7V. Alternatively, since half of −7V is −3.5V, Vneg+2*Vth2 is equal to −5.6V, and VCGB-2*Vth1 is equal to −1.4V, Vbias1 and Vbias2 may be a value between −1.4V and −5.6V. Since differences between −3.5 and −5.6V and between −3.5 and −1.4V, are both 2.1V, the second offset value is 2.1V. In Table 2, both Vbias1 and Vbias2 being −4V can achieve a better effect.

XPCG will change from 0 to −7V (corresponding to the selected bit) or 0V (corresponding to the non-selected bit).

CG will change from 0 to −7V (corresponding to the selected bit) or 0V (corresponding to the non-selected bit).

Vneg will change from 0 to −7V.

Xdbias is 0V or −4V. For example, in a case that xdbias is −4V and XPCG is −7V, the drain voltage of the PMOS transistor MP101 is the voltage of the node A. The voltage of the node A is Vbias1+Vth1. Vbias1 is equal to −4V. At this time, the difference between the node A and the signal selb is Vth1, so the PMOS transistor MP101 is turned on.

In this embodiment of this application, a pull-up circuit 302 and a pull-down circuit 305 in the driving circuit, as well as an upper switching circuit 303 and a lower switching circuit 304 located between the two are provided. Control ends of the upper switching circuit 303 and the lower switching circuit 304 can be respectively configured with first bias voltage Vbias1 and second bias voltage Vbias2. The first bias voltage Vbias1 limits the control end voltage of the upper switching circuit 303 and can limit the minimum voltage that can be reached by the first pull-up node A at the connection between the pull-up circuit 302 and the upper switching circuit 303 on the premise of ensuring that the upper switching circuit 303 is conducted. Similarly, the second bias voltage Vbias2 limits the control end voltage of the lower switching circuit 304 and can limit the maximum voltage that can be reached by the first pull-down node E at the connection between the pull-down circuit 305 and the lower switching circuit 304 on the premise of ensuring that the lower switching circuit 304 is conducted. Therefore, this application can adjust the actual withstand voltage of each transistor in the driving circuit by adjusting the first bias voltage Vbias1 and the second bias voltage Vbias2. Therefore, this embodiment of this application can adjust the withstand voltage of each transistor in the driving circuit, so that the high voltage of the driving circuit will not be fully borne by each transistor, and the voltage withstanding capacity actually required for the transistor is reduced. Therefore, transistors with a thinner gate oxide structure can be adopted, thus effectively reducing the area of the driving circuit and reducing the area of the entire flash memory.

The pull-up circuit 302 and the pull-down circuit 305 in this embodiment of this application may also be configured as an interlocked structure and form two mutually opposite paths, which can further optimize the performance of the circuit.

This application is described above in detail through the specific embodiments, which, however, do not constitute limitations to this application. Without departing from the principle of this application, those skilled in the art may also make many modifications and improvements, which should also be considered as included in the scope of protection of this application.

What is claimed is:

1. A control gate line driving circuit of a flash memory, comprising an input circuit, a pull-up circuit, an upper switching circuit, a lower switching circuit, and a pull-down circuit, wherein
a control end of the input circuit is connected to a first selection signal, the first selection signal is configured to select an operation area of the flash memory, an input end of the input circuit is connected to control gate line input voltage in each row in the operation area, and an output end of the input circuit is connected to a first pull-up node;
the pull-up circuit is connected between control gate positive power supply voltage and the first pull-up node;
the upper switching circuit is connected between the first pull-up node and a first intermediate node, and a control end of the upper switching circuit is connected to first bias voltage; the voltage of the first intermediate node serves as control gate line output voltage in each row;
the lower switching circuit is connected between the first intermediate node and a first pull-down node, and the control end of the upper switching circuit is connected to second bias voltage;
the pull-down circuit is connected between the first pull-down node and control gate negative power supply voltage;
a high level of the control gate line input voltage is a first voltage value, and a low level is a second voltage value; the first voltage value is equal to the control gate positive power supply voltage;
a high level of the first selection signal is a third voltage value, and a low level is a fourth voltage value; the fourth voltage value is taken in a case that the first selection signal is enabled;
when the flash memory is operated, the first selection signal is enabled, and the control gate line driving circuit comprises two working states;
a first working state is as follows:
the control gate line input voltage is the first voltage value; the first voltage value is greater than or equal to the fourth voltage value to enable a connection input end of the input circuit to be conducted with a transistor of the first pull-up node;
the pull-up circuit enables the first pull-up node to be connected to the control gate positive power supply voltage, and the voltage of the first pull-up node is equal to the control gate positive power supply voltage;
the upper switching circuit enables the first pull-up node be conducted with the first intermediate node under the control of the first bias voltage, and the voltage of the first intermediate node is equal to the control gate positive power supply voltage;
the lower switching circuit enables the first intermediate node to be conducted with the first pull-down node under the control of the second bias voltage, the voltage of the first pull-down node is equal to the second bias voltage minus second threshold voltage, and the second threshold voltage is the threshold voltage of a transistor of the lower switching circuit;
the pull-down circuit enables the first pull-down node to be disconnected from the control gate negative power supply voltage;
the maximum withstand voltage of a transistor of the pull-down circuit is Vbias2-Vth2-Vneg, where Vias2 is the second bias voltage, Vth2 is the second threshold voltage, and Vneg is the control gate negative power supply voltage;
the maximum withstand voltage of the transistor of the lower switching circuit is VCGB-Vbias2, where VCGB is the control gate positive power supply voltage;
the maximum withstand voltage of a transistor of the upper switching circuit is VCGB-Vbias1, where Vias1 is the first bias voltage;
the maximum withstand voltage of a transistor of the input circuit is VCGB-xdbias, where xdbias represents the fourth voltage value;
a second working state is as follows:
the control gate line input voltage is the second voltage value;
the pull-up circuit enables the first pull-up node to be disconnected from the control gate positive power supply voltage;
the upper switching circuit enables the first pull-up node to be conducted with the first intermediate node under the control of the first bias voltage, the voltage of the first pull-up node is equal to the first bias voltage plus the first threshold voltage, and the first threshold voltage is an absolute value of the threshold voltage of the transistor of the upper switching circuit; the first bias voltage is greater than or equal to the fourth voltage value to enable the connection input end of the input circuit to be conducted with the transistor of the first pull-up node;
the lower switching circuit enables the first intermediate node to be conducted with the first pull-down node under the control of the second bias voltage, and enables the voltage of the first intermediate node to be equal to the voltage of the first pull-down node;
the pull-down circuit enables the first pull-down node to be connected to the control gate negative power supply voltage, and enables the voltage of the first pull-down node to be equal to the control gate negative power supply voltage;
the maximum withstand voltage of a transistor of the pull-up circuit is VCGB-Vbias1-Vth1, where Vth1 is the first threshold voltage;
the maximum withstand voltage of the transistor of the upper switching circuit is Vbias1-Vneg;
the maximum withstand voltage of the transistor of the lower switching circuit is Vbias2-Vneg;
the maximum withstand voltage of the transistor of the input circuit is Vbias1+Vth1-xpcgmin, where xpcgmin represents the second voltage value, the second voltage value is less than or equal to the fourth voltage value, and the second voltage value is greater than or equal to the control gate negative power supply voltage;
the magnitude of the first bias voltage is configured to satisfy the requirement on the maximum withstand voltage of the transistor of the upper switching circuit in the first working state, and satisfy the requirement on the maximum withstand voltage of the transistor of the pull-up circuit, the transistor of the upper switching circuit and the transistor of the input circuit in the second working state;
the magnitude of the second bias voltage is configured to satisfy the requirement on the maximum withstand voltage of the transistor of the pull-down circuit and the transistor of the lower switching circuit in the first working state, and satisfy the requirement on the maximum withstand voltage of the transistor of the lower switching circuit in the second working state;
the magnitude of the fourth voltage value is configured to satisfy the requirement on the maximum withstand voltage of the transistor of the input circuit in the second working state.

2. The control gate line driving circuit of the flash memory according to claim 1, wherein the control gate line driving circuit of the flash memory further comprises a second pull-up node, a second intermediate node and a second pull-down node;
the levels of the second pull-up node and the first pull-up node are mutually inverted and interlocked; the second pull-up node is connected to a control end of a connecting transistor between the first pull-up node and the control gate positive power supply voltage; the first pull-up node is connected to a control end of a connecting transistor between the second pull-up node and the control gate positive power supply voltage;
the levels of the second pull-down node and the first pull-down node are mutually inverted and interlocked; the second pull-down node is connected to a control end of a connecting transistor between the first pull-down node and the control gate negative power supply voltage; the first pull-down node is connected to a control end of a connecting transistor between the second pull-down node and the control gate negative power supply voltage;
the levels of the second intermediate node and the first intermediate node are mutually inverted.

3. The control gate line driving circuit of the flash memory according to claim 2, wherein the input circuit comprises a first PMOS transistor and a second PMOS transistor;
a gate of the first PMOS transistor is connected to the first selection signal, a source of the first PMOS transistor is connected to the corresponding control gate line input voltage, and a drain of the first PMOS transistor is connected to the first pull-up node;
a gate of the second PMOS transistor is connected to a second selection signal, the second selection signal is an inverted signal of the first selection signal, and a source of the second PMOS transistor is connected to second positive power supply voltage, and a drain of the first PMOS transistor is connected to the first pull-up node; the third voltage value is equal to the second positive power supply voltage, and the second PMOS transistor is turned off in a case that the first selection signal is enabled.

4. The control gate line driving circuit of the flash memory according to claim 2, wherein the second positive power supply voltage is equal to the control gate positive power supply voltage.

5. The control gate line driving circuit of the flash memory according to claim 2, wherein the first selection signal and the second selection signal are output by a level shifting circuit;
a power supply end of the level shifting circuit is connected to the second positive power supply voltage;
a grounding end of the level shifting circuit is connected to third grounding end power supply voltage, and the magnitude of the third grounding end power supply voltage is the fourth voltage value.

6. The control gate line driving circuit of the flash memory according to claim 5, wherein a first input end of the level shifting circuit is connected to a first decoding signal output by a logic decoding circuit, a second input end of the level shifting circuit is connected to a second decoding signal, and the second decoding signal is an inverted signal of the first decoding signal;
the first selection signal and the first decoding signal are mutually inverted;
the high levels of the first decoding signal and the second decoding signal are both power supply voltage and the low levels are both 0V.

7. The control gate line driving circuit of the flash memory according to claim 2, wherein the pull-up circuit comprises a third PMOS transistor and a fourth PMOS transistor;
a source of the third PMOS transistor and a source of the fourth PMOS transistor are both connected to the control gate positive power supply voltage;
a drain of the third PMOS transistor and a gate of the fourth PMOS transistor are connected to the first pull-up node;
a drain of the fourth PMOS transistor and a gate of the third PMOS transistor are connected to the second pull-up node.

8. The control gate line driving circuit of the flash memory according to claim 7, wherein the upper switching circuit comprises a fifth PMOS transistor and a sixth PMOS transistor;
a source of the fifth PMOS transistor is connected to the first pull-up node, a drain is connected to the first intermediate node, and a gate is connected to the first bias voltage;
a source of the sixth PMOS transistor is connected to the second pull-up node, a drain is connected to the second intermediate node, and a gate is connected to the first bias voltage.

9. The control gate line driving circuit of the flash memory according to claim 8, wherein the lower switching circuit comprises a first NMOS transistor and a second NMOS transistor;
a source of the first NMOS transistor is connected to the first pull-down node, a drain is connected to the first intermediate node, and a gate is connected to the second bias voltage;
a source of the second NMOS transistor is connected to the second pull-down node, a drain is connected to the second intermediate node, and a gate is connected to the second bias voltage.

10. The control gate line driving circuit of the flash memory according to claim 9, wherein the pull-down circuit comprises a third NMOS transistor and a fourth NMOS transistor;
a source of the third NMOS transistor and a source of the fourth NMOS transistor are both connected to the control gate negative power supply voltage;
a drain of the third NMOS transistor and a gate of the fourth NMOS transistor are connected to the first pull-down node;
a drain of the fourth NMOS transistor and a gate of the third NMOS transistor are connected to the second pull-down node.

11. The control gate line driving circuit of the flash memory according to claim 10, wherein the maximum value of the first bias voltage is less than or equal to VCGB-2*Vth1;
the minimum value of the second bias voltage is greater than or equal to Vneg+2*Vth2.

12. The control gate line driving circuit of the flash memory according to claim 11, wherein each memory cell of the flash memory is a split-gate floating gate device;
the split-gate floating gate device comprises a first source-drain region and a second source-drain region, a plurality of split first gate structures with floating gates located between the first source-drain region and the second source-drain region, and a second gate structure located between the first gate structures; the first gate structure is provided with the control gate located at the tops of the floating gates; each floating gate is configured to store charges and corresponds to a memory bit;
in a memory array of the flash memory, the control gates of each first gate structure in the same row are all connected to a control gate line in the same row;
when the flash memory is operated, operations in the same operation area comprise performing voltage driving on the control gate lines in a plurality of rows, and each control gate line is connected to the control gate line output voltage of one in the same row.

13. The control gate line driving circuit of the flash memory according to claim 12, wherein the split-gate floating gate device is a dual-split-gate floating gate device, and the number of the first gate structures is two.

14. The control gate line driving circuit of the flash memory according to claim 13, wherein operations on the flash memory comprise programming, reading, and erasing;
during programming, the control gate line connected to a selected memory bit of a selected memory cell is connected to control gate line programming positive high voltage, and the control gate line connected to a non-selected memory bit is connected to 0V voltage;
during reading, the control gate line connected to the non-selected memory bit of the selected memory cell is connected to control gate line reading positive high voltage, and the control gate line connected to the selected memory bit of the selected memory cell is connected to 0V voltage; the control gate line reading positive high voltage is less than the control gate line programming positive high voltage;
during erasing, the control gate line connected to the selected memory bit of the selected memory cell is connected to control gate line erasing negative high voltage, and the control gate line connected to the non-selected memory bit is connected to 0V voltage.

15. The control gate line driving circuit of the flash memory according to claim 14, wherein during programming, VCGB is the control gate line programming positive high voltage, Vneg is 0V, and the first bias voltage and the second bias voltage are both configured to half of the control gate line programming positive high voltage or half of the control gate line programming positive high voltage plus or minus a first offset value, the first offset value is less than or equal to half of the control gate line programming positive high voltage minus (Vneg+2*Vth2), and the first offset value is less than or equal to (VCGB-2*Vth1) minus half of the control gate line programming positive high voltage; the fourth voltage value is configured to be equal to the first bias voltage;
during reading, VCGB is the control gate line reading positive high voltage, Vneg is 0V, the power supply voltage is less than (VCGB-2*Vth1), and the first bias voltage is the power supply voltage; the power supply voltage is less than (Vneg+2*Vth2), and the second bias voltage is a value between (Vneg+2*Vth2) and VCGB;
during erasing, VCGB is 0V, Vneg is the control gate line erasing negative high voltage, and the first bias voltage and the second bias voltage are both configured to half of the control gate line erasing negative high voltage or half of the control gate line erasing negative high voltage plus or minus a second offset value, the second offset value is less than or equal to half of the control gate line erasing negative high voltage minus (Vneg+2*Vth2), and the second offset value is less than or equal to (VCGB-2*Vth1) minus half of the control gate line erasing negative high voltage; the fourth voltage value is configured to be equal to the first bias voltage.

16. The control gate line driving circuit of the flash memory according to claim 15, wherein during programming, the control gate line programming positive high voltage is 8V, and the first bias voltage and the second bias voltage are both 4V; the first voltage value of the control gate line input voltage is equal to 8V, and the second voltage value is less than or equal to 4V;
during reading, the control gate line reading positive high voltage is 4V, and the second bias voltage is 3V; the first voltage value of the control gate line input voltage is equal to 4V, and the second voltage value is less than or equal to 0V;
during erasing, the control gate line erasing negative high voltage is −7V, and the first bias voltage and the second bias voltage are both −4V; the first voltage value of the control gate line input voltage is equal to 0V, and the second voltage value is less than or equal to −7V.
